(19) United States
(12) Patent Application Publication
(10) Pub. No.: US 2001/0013771 A1
(43) Pub. Date: Aug. 16, 2001

(54) Phase failure monitoring

(76) Inventor: Roland Wasmer, Wegmattstrasse (CH)

Correspondence Address: Harold C. Moore, Maginot, Addison & Moore, Bank One Center/Tower, 111 Monument Circle, Suite 3000, Indianapolis, IN, 46204-5130, US

(21) Appl. No.: 09/728,002

(22) Filed: Dec. 1, 2000

(30) Foreign Application Priority Data
Dec. 3, 1999 (DE) 19958369.2

(51) Int. Cl. G01R 25/00

(52) U.S. Cl. 324/86

(57) ABSTRACT

In order in an electronic apparatus (1a), in particular an electricity meter (1b), to afford a simple way of monitoring the failure of the reference phase (L2), it is provided that the angle (α) between two detected interlinked voltages (UL2/L3 and UL2/L1) is measured. When a predeterminable limit value (αG) for the angle (α) is exceeded, a fault signal is produced, which represents failure of the reference or datum phase (L2). Preferably an Aron circuit is used.

### BACKGROUND OF THE INVENTION

1. Field of the Invention

The invention concerns a method of phase failure monitoring and an electrical apparatus, in particular an electricity meter, with phase failure monitoring.

2. Description of the Prior Art

It is known generally in relation to an electricity meter to use the so-called Aron circuit for ascertaining the energy consumption across all phases. This circuit serves to reduce the number of current and voltage transformers required. In that situation, instead of the three phase voltages of a three-phase rotary current network, only two interlinked voltages and two currents are detected. Should the occasion arise it is optionally possible by vectorial addition or summing of the two interlinked voltages to produce or reproduce the voltage of the third phase.

If in operation the common phase (also referred to as the reference phase) of the two interlinked voltages should fail, the measurement result is falsified by virtue of the absence of the reference potential. For that purpose it is known from a practical context to ascertain the missing reference phase by simple measurement of the voltage amplitude. More specifically, if the reference phase is missing, the values of the interlinked voltages are reduced symmetrically to smaller values. In regard to modern present-day “Wide Voltage Range” mains units and/or power packs, it is necessary to design the voltage monitoring for a number of limits, whereby that monitoring method becomes excessively unreliable.

### SUMMARY OF THE INVENTION

The object of the present invention is to afford a simple possible way of monitoring the failure of the reference phase in a three-conductor system.

In this respect, a first aspect of the present invention provides a method of phase failure monitoring in an electronic apparatus, such as an electricity meter, and the following method steps are provided for rotary voltage:

two interlinked voltages of a three-phase rotary current network are detected,

the phase angle between the two interlinked voltages is ascertained and compared to a predetermined limit angle, and

in the event of the predetermined limit angle being exceeded by the ascertained phase angle a fault signal is produced for the failure of the common reference voltage between the two detected voltages.

In this way phase failure monitoring can be implemented in a simple manner by angle measurement. An angle measurement member which is already present in the electricity meter can possibly be used for the angle measurement procedure. In a digital construction, there is also a saving on memory space. In this respect the two detected interlinked voltages are digitized prior to further processing.

It is advantageously possible by means of addition or summation of the two detected interlinked voltages to reproduce the third interlinked voltage. That means that this parameter is also available for processing.

In a preferred embodiment the three phases of the three-phase current network are connected to an Aron circuit, by means of which the energy consumption of a load connected to the three-phase network is ascertained. In that connection, the Aron circuit can be simulated by suitable measuring arrangements in the form of hardware or also in a situation involving digital processing as a computing step in a program. A simple hardware solution is afforded when using Hall elements in the input portion of an electricity meter. The method of phase failure monitoring can be used generally in relation to electrical or electronic apparatuses.

Preferably the electronic apparatus is in the form of an electricity meter, wherein all interlinked voltages can be used for ascertaining an energy consumption of a load on the three-phase network. According to a second aspect of the present invention, the apparatus has the following components:

first and second voltage sensors for detecting two interlinked voltages of a three-phase rotary current network, and

an angle measuring device having a limit value member and a signaling member,

wherein the two detected interlinked voltages are fed to the angle measuring device and, in the event of a predetermined limit value being exceeded by the measured phase angle between the detected interlinked voltages, a signal can be produced by the signaling member for failure of the common reference voltage between the two detected voltages.

### BRIEF DESCRIPTION OF THE DRAWINGS

Preferred embodiments of the invention, further advantages and details are described more fully hereinafter with reference to the drawing in which:

FIG. 1 shows a block circuit diagram of an electronic apparatus according to the invention,

FIG. 2 shows a further block circuit diagram of a digital apparatus, and

FIG. 3 shows a voltage vector diagram.

### DESCRIPTION OF THE PREFERRED EMBODIMENTS

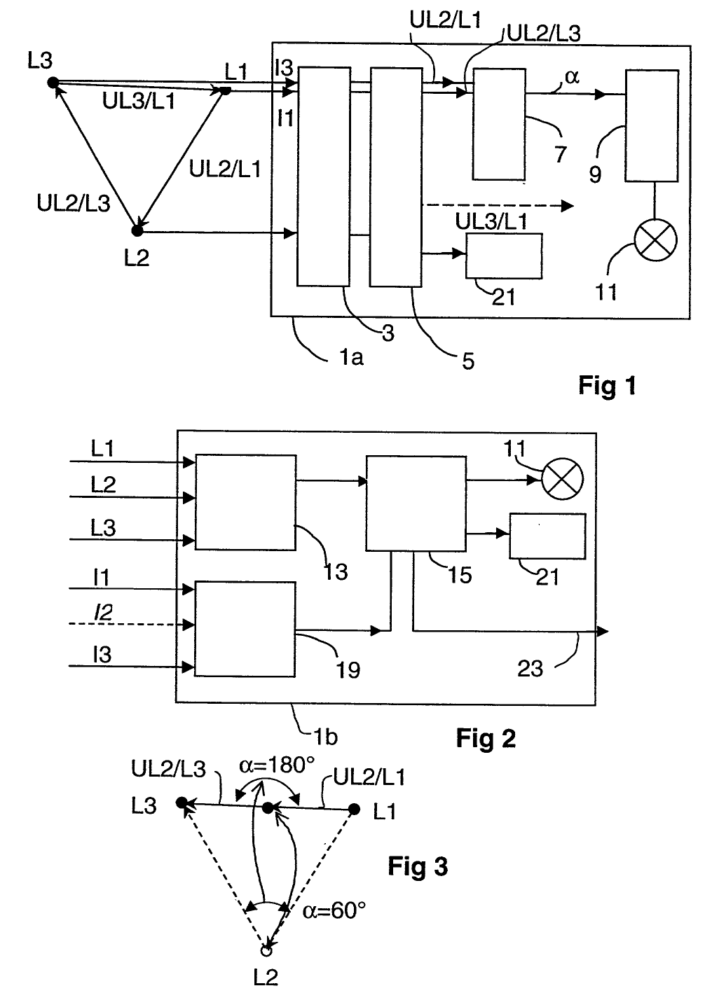

FIG. 1 shows an electrical diagram of a three-conductor rotary current network, comprising the phases L1, L2 and L3. Three voltage transformers or voltage sensors are used in the normal case for detection of the respective phase voltages or three interlinked voltages. In the so-called Aron circuit only two interlinked voltages and two currents are detected. If necessary, it is possible by means of geometrical or vectorial summation or subtraction to calculate, ascertain or simulate the third voltage.

In the present case for example the two interlinked voltages UL2/L3 and UL2/L1 are fed to a measuring module 3 of an electronic apparatus 1a which is preferably in the form of an electronic electricity meter. The measuring module 3 includes conventional voltage detection means, for example voltage dividers or also voltage transformers. The detected interlinked voltages UL2/L3 and UL2/L1 are fed to a logic switching module 5 which includes means for simulation of the Aron circuit. Those means can be for example two measuring arrangements for ascertaining the energy consumption of a load connected to the rotary current network, in which respect a phase current and an interlinked voltage are respectively fed to the measuring arrangements. The measuring arrangements or the logic switching module 5 can also include display means for energy consumption. In the present case for that purpose a display module 21 is connected to the logic switching module 5 which can be for example in the form of an LCD-display.

If necessary it is optionally also possible to simulate the third interlinked voltage UL3/L1 in the logic switching module 5. Starting from the voltage direction arrows shown in FIG. 1, the third interlinked voltage UL3/L1 arises as between L3 and L1 out of an addition of −UL2/L3 and −UL2/L1. Accordingly then all interlinked voltages of the three-phase current network are available and can be used for further processing in the electronic apparatus 1. A use by way of example will be discussed in greater detail hereinafter, in the description relating to FIG. 2.

It is essential for correct functioning of the electronic apparatus 1 that the reference voltage or reference phase, in the present case the phase L2, is also present. If the reference phase fails, for example due to a break in a conductor, that entails a voltage vector variation corresponding to FIG. 3. In that case the two interlinked voltages UL2/L3 and UL2/L1 collapse into one plane. In that situation the lengths of their voltage vectors are reduced by about half.

In order to detect that failure, it is provided in the present case that the phase angle α between the two voltages UL2/L3 and UL2/L1 is measured with an angle measuring device or angle measuring member 7. The measurement angle α is monitored in a subsequent limit value member 9 to ascertain when a predeterminable limit value αG is exceeded. As shown in FIG. 3, it can be readily perceived that, upon the failure of the reference phase L2, the angle α between the two interlinked voltages UL2/L3 and UL2/L 1 increases abruptly from generally 60° to about 180° (in the case of the reverse direction of rotation from 300° to 180°). Then for example a limit angle αG of the order of magnitude of 120° (or 240° respectively) is set in the limit value member 9. Having regard to the direction of rotation, it may also be desirable to provide a limit value band, for example between 120° and 240°.

If a phase angle α which is in an inadmissible range is detected, a fault signal is produced, which can possibly displayed by way of an indicator 11, for example a lamp or an LCD-element as a signaling member. It will be appreciated that it is also possible to envisage further signaling means or subsequent operating procedures for processing the fault message. For that purpose the fault signal can be outputted by way of a line or an interface which is not shown in greater detail here. Reference is also directed in that respect to FIG. 2 with the interface 23.

FIG. 2, to represent an alternative embodiment, shows a block circuit diagram of an electricity meter 1b in a simplified configuration. This electronic apparatus involves digital signal processing. After detection of the interlinked voltages UL2/L3 and UL2/L1, they are digitized in an A/D-converter 13 and fed to a computer 15. As currents are also required in the phases, for ascertaining the energy consumed by a load, they are also fed to the electricity meter 1b by way of suitable sensors (not shown). The current I2 is not required when using the Aron circuit. It is therefore shown in broken line. The detected and digitized currents I1, I3 and possibly I2 also go to the computer 15 by way of a further A/D-converter 19. It will be appreciated that matching means, for example resistors and filters, for measurement signal matching may also be connected upstream of the A/D-converters 13 and 19. All embodiments described herein are also suitable for measurement value detection in conjunction with one or more Hall elements, in particular in the configuration with the Aron circuit.

If necessary, by means of a program, in the computer the missing interlinked voltage UL3/L1 can be ascertained by computation in the manner already described hereinbefore. Then, on the basis of the available interlinked voltages UL2/L3, UL2/L1 and UL3/L1 and the currents I1, I2 and I3 of the phases (in the case of the Aron circuit, with only two currents and two voltages), the energy consumption of a load arranged in the network can be calculated on the basis of the generally known methods and formulae. The energy consumption can then be displayed for example by way of the display module 21 and/or outputted by way of the interface 23. It will be appreciated that it is also possible to implement other interfaces which are known in accordance with the state of the art and further processing devices within the electricity meter 1b. In the present case—possibly also indirectly—the computer 15 controls an indicator 11 for displaying the reference voltage failure. A signal option can possibly also be provided, within the display module 21.

It is also essential in regard to this embodiment that the above-described function of reference voltage monitoring is effected by measurement of a phase angle between two interlinked voltages. The method steps with the angle measuring member 7 and the limit value member 9 are then executed as program units or steps in the computer 15. The function of the reference voltage monitoring procedure can advantageously be used in conjunction with the Aron circuit which is then also implemented by computation in the computer 15 with a program. It will be appreciated that the computer 15 has conventional auxiliary devices which are necessary for its operation, for example a memory (not shown) for holding values and data and storage of programs.

This alternative configuration is desirable in particular in regard to the configuration in the form of a digital electricity meter as, in the case of digital meters, angle measurement can possibly be provided in any case in the form of a software program for ascertaining the rotary field direction. That program module can then preferably be used for the object to be attained herein. Reference voltage monitoring can advantageously also be used as indirect power-theft indicator (anti-tampering). In a construction in the form of a digital meter, different divisions of the A/D-converters and also additional processors within the context of generally known digital technology are also possible.

I claim:

1. A method of phase failure monitoring in an electronic apparatus, such as an electricity meter, for rotary voltage, comprising the following steps:
two interlinked voltages of a three-phase rotary current network are detected,
the phase angle between the two interlinked voltages is ascertained and compared to a predetermined limit angle, and
in the event of the predetermined limit angle being exceeded by the ascertained phase angle a fault signal is produced for the failure of the common reference phase between the two detected voltages.

2. A method as set forth in claim 1, wherein the two detected interlinked voltages are digitized prior to further processing.

3. A method as set forth in claim 1, wherein the third interlinked voltage is simulated by means of addition or summation of the two detected interlinked voltages.

4. A method as set forth in claim 1, wherein the three phases of the rotary current network are connected to an Aron circuit, by means of which an energy consumption of a load connected to the rotary current network is ascertained.

5. A method as set forth in claim 3, wherein two or all three interlinked voltages are used to ascertain an energy consumption of a load on the rotary current network.

6. An electronic apparatus, such as an electricity meter, for rotary voltage, comprising:
first and second voltage sensors for detecting two interlinked voltages of a three-phase rotary current network, and
an angle measuring device having a limit value member and a signaling member,
wherein the two detected interlinked voltages are fed to the angle measuring device and, in the event of a predetermined limit value being exceeded by the measured phase angle between the detected interlinked voltages, a signal is produced by the signaling member for failure of the common reference phase between the two detected voltages.
